(19) United States
(12) Patent Application Publication
(10) Pub. No.: US 2008/0268592 A1
(43) Pub. Date: Oct. 30, 2008

(54) Flash memory device and method of fabricating the same

(75) Inventors: Weon-Ho Park, Suwon-si (KR); Jeong-Uk Han, Suwon-si (KR); Yong-Tae Kim, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/004,698

(22) Filed: Dec. 21, 2007

(30) Foreign Application Priority Data
Mar. 12, 2007 (KR) 10-2007-0024126

(51) Int. Cl. H01L 21/8242

(52) U.S. Cl. 438/253

(57) ABSTRACT

Provided are a flash memory device and a method of fabricating the same. The method includes forming a first dielectric layer on an active region of a semiconductor substrate. A first conductive layer is formed on the semiconductor substrate having the first dielectric layer. A mask pattern is formed on the first conductive layer. Using the mask pattern as an etch mask, the first conductive layer is etched to form a first conductive pattern narrowing from its upper surface toward its middle portion. A second dielectric layer is formed on the semiconductor substrate having the first conductive pattern. A second conductive pattern crossing the active region adjacent to the first conductive pattern and partially covering the first conductive pattern is formed on the semiconductor substrate having the second dielectric layer.

### CROSS-REFERENCE TO RELATED APPLICATION

This application claims priority under 35 U.S.C. 119 to Korean Patent Application No. 10-2007-0024126, filed on Mar. 12, 2007, the disclosure of which is hereby incorporated herein by reference in its entirety.

### BACKGROUND OF THE INVENTION

1. Field of the Invention

The present invention relates to a semiconductor device and a method of fabricating the same, and more particularly, to a flash memory device having a split-gate structure and a method of fabricating the same.

2. Description of the Related Art

A flash memory device is a nonvolatile memory device capable of maintaining data even when power is removed. The flash memory device is a highly-integrated device developed by combining merits of an erasable programmable read only memory (EPROM) and an electrically erasable programmable read only memory (EEPROM).

A conventional flash memory cell has a stacked-gate structure including a tunnel oxide layer, a floating gate, an inter-gate insulating layer, and a control gate stacked on a semiconductor substrate between a source and a drain. The stacked-gate structure has a problem of over-erase, and a flash memory cell having a split-gate structure was proposed to solve the problem.

FIGS. 1A to 1D are cross-sectional views illustrating a method of fabricating a conventional split-gate flash memory device.

Referring to FIG. 1A, a first gate dielectric layer 5 and a first polysilicon layer 10 are sequentially stacked on an active region 3 of a semiconductor substrate 1. A hard mask 15 is formed on the first polysilicon layer 10, the hard mask layer 15 having an opening 15a exposing a predetermined region of the first polysilicon layer 10. The hard mask 15 is formed of a silicon nitride layer.

Referring to FIG. 1B, using the hard mask 15 as an oxidation resistant mask, the first polysilicon layer 10 exposed through the opening 15a is thermally oxidized at high temperature for a long time, and thereby a partially oxidized layer 20 is formed. For example, the first polysilicon layer 10 can be thermally oxidized at 900° C. to 1100° C. for 5 to 10 hours. In this way, the semiconductor substrate 1 is exposed to high temperature while the partially oxidized layer 20 is being formed.

The semiconductor substrate can include a low-power transistor region as well as a flash memory cell region. Channel impurity ions for adjusting the threshold voltage of a lower-power transistor can be implanted into such a low-power transistor region. In addition, the channel impurity ions can be implanted to prevent punch-through of the transistor. The concentration profile of the channel impurity ions can change during a thermal process for forming the partially oxidized layer 20. This can cause a problem particularly when a channel length is shortened, because the threshold voltage of the low-power transistor can be changed by a minute change in channel impurity concentration with the reduction of the channel length.

Referring to FIG. 1C, the hard mask (15 in FIG. 1B) is removed using the partially oxidized layer 20 as an etch mask. Then, the polysilicon layer 10 is etched using the partially oxidized layer 20 as an etch mask to form a floating gate 10a. Subsequently, a second gate dielectric layer 25 is formed on the semiconductor substrate 1 having the floating gate 10a.

Referring to FIG. 1D, a second polysilicon layer is formed on the semiconductor substrate 1 having the second gate dielectric layer 25. Subsequently, the second polysilicon layer is patterned to form a control gate 30 crossing the active region 3 and partially overlapping the floating gate 10a. Source and drain regions 35 are formed in the active region 3 adjacent to the control gate 30 and the floating gate 10a.

As described above, in order to form the floating gate 10a, the partially oxidized layer 20 has to be formed at high temperature. The process of forming the partially oxidized layer 20 at high temperature makes it difficult to simultaneously form a semiconductor device including the low-power transistor in combination with a flash memory device.

Meanwhile, the second gate dielectric layer 25 is turned at a right angle at a portion where it is adjacent to the control gate 30, the floating gate 10a, and the active region 3 Thus, an electric field can be concentrated in the portion where the second gate dielectric layer 25 is adjacent to the control gate 30, the floating gate 10a, and the active region 3. Consequently, it is difficult to ensure the reliability of the second gate dielectric layer 25.

A method of forming a flash memory cell having a split-gate structure is disclosed in U.S. Pat. No. 6,821,849 B2 entitled “Split gate flash memory cell and manufacturing method thereof” by Chang. According to Chang, a floating gate is formed by the process described with reference to FIGS. 1B and 1C. As described with reference to FIG. 1B, the method of forming a floating gate can deteriorate the threshold voltage characteristics of a scaled-down low-power transistor.

### SUMMARY OF THE INVENTION

In accordance with the present invention there is provided a method of fabricating a split-gate flash memory device using a technique of forming floating gates without a high-temperature process.

Also in accordance with the invention there is provided a split-gate flash memory device employing floating gates formed without a high-temperature process.

In one aspect, the present invention is directed to a method of fabricating a flash memory device having a split-gate structure. The method includes forming a first dielectric layer on an active region of a semiconductor substrate. A first conductive layer is formed on the semiconductor substrate. A mask pattern is formed on the first conductive layer. Using the mask pattern as an etch mask, the first conductive layer is etched to form a first conductive pattern narrowing from its upper surface toward its middle portion. A second dielectric layer is formed on the semiconductor substrate having the first conductive patterns. A second conductive pattern crossing the active region adjacent to the first conductive pattern and partially covering the first conductive pattern is formed on the semiconductor substrate having the second dielectric layer.

The first conductive layer can contain implanted atoms.

In the first conductive layer, the concentration of the implanted atoms can increase from the upper surface of the first conductive layer toward the middle portion.

In the first conductive layer, the concentration of the implanted atoms can decrease from the middle portion of the first conductive layer to a bottom of the first conductive layer.

Forming the first conductive layer can include forming an undoped silicon layer on the semiconductor substrate having the first dielectric layer, and implanting first impurity ions into the undoped silicon layer to form a silicon layer containing the implanted atoms.

After forming the second conductive pattern, the method can further comprise performing a thermal process so that the implanted atoms are diffused and uniformly distributed into the first conductive pattern.

The implanted atoms can include at least one of phosphorus (Ph) and arsenic (As).

The first conductive pattern can be widened from its middle portion to its bottom.

The first conductive pattern can be formed to have concave sidewalls.

The first conductive layer can be etched using a dry etch process.

The method can further comprise forming a first photoresist pattern having a first opening exposing a portion of the active region adjacent to the first conductive pattern on the semiconductor substrate having the second conductive pattern, implanting impurity ions into the active region exposed through the first opening using the first photoresist pattern as an ion implantation mask to form a first impurity region, removing the first photoresist pattern, and performing a first annealing process to activate the impurity ions implanted into the first impurity region.

The method can further comprise forming a second photoresist pattern having a second opening exposing the active region adjacent to the second conductive pattern on the semiconductor substrate having the second conductive pattern, implanting impurity ions into the active region exposed through the second opening using the second photoresist pattern as an ion implantation mask to form a second impurity region, removing the second photoresist pattern, and performing a second annealing process to activate the impurity ions implanted into the second impurity region.

In the above, the second thermal process can be performed at a lower temperature than the first thermal process.

In another aspect, the present invention is directed to a flash memory device having a split-gate structure. The flash memory device includes a first conductive pattern disposed on an active region of a semiconductor substrate, the first conductive pattern having a flat upper surface and narrowing from its upper surface toward its middle portion. A first dielectric layer is interposed between the first conductive pattern and the active region. A second conductive pattern crosses the active region adjacent to the first conductive pattern and overlaps the first conductive pattern. A second dielectric layer having a portion interposed between the second conductive pattern and another portion interposed between the first conductive pattern and between the second conductive pattern and the active region.

The first conductive pattern can be formed of a doped silicon layer.

The second conductive pattern can cover sidewalls of the first conductive pattern while partially overlapping the upper surface of the first conductive pattern.

The first conductive pattern can be spaced apart from the second conductive pattern by the thickness of the second dielectric layer.

The first conductive pattern can be widened from its middle portion to its bottom.

The first conductive pattern can have concave sidewalls.

The flash memory device can further comprise a first impurity region disposed in the active region adjacent to the first conductive pattern, and a second impurity region disposed in the active region adjacent to the second conductive pattern. Here, the second impurity region can be a shallower junction than the first impurity region.

### BRIEF DESCRIPTION OF THE DRAWINGS

The foregoing and other objects, features and advantages of the invention will become more apparent from the following more particular description of exemplary embodiments in accordance with the invention and the accompanying drawings. The drawings are not necessarily to scale, emphasis instead being placed upon illustrating the principles and aspects of the invention.

FIGS. 1A to 1D are cross-sectional views illustrating a prior art method of fabricating a conventional flash memory device.

FIG. 2 is a plan view of an embodiment of a flash memory device according to an aspect of the present invention.

FIGS. 3A to 3D are cross-sectional views illustrating an embodiment of a method of fabricating a flash memory device according to an aspect of the present invention.

FIG. 4 is a graph schematically showing impurity concentration depending on the depth of a conductive layer according to aspects of the present invention.

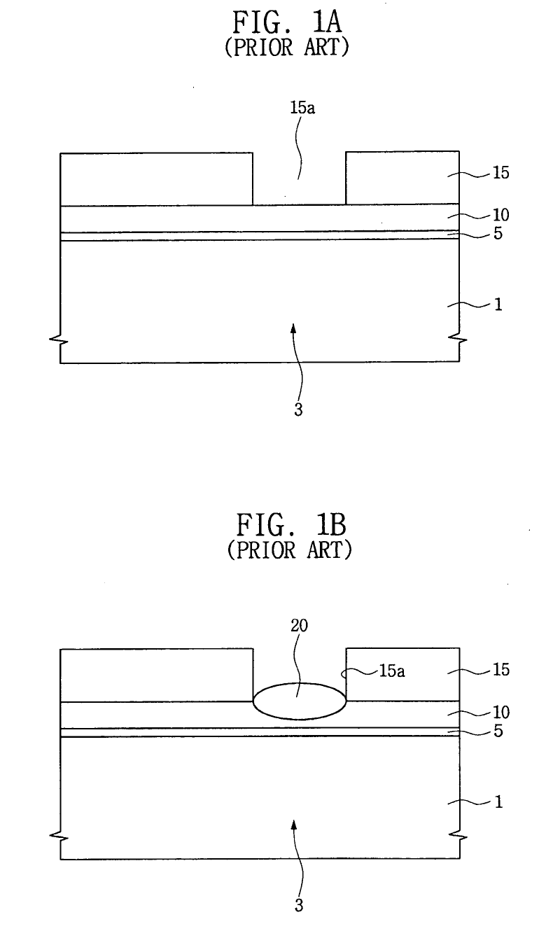

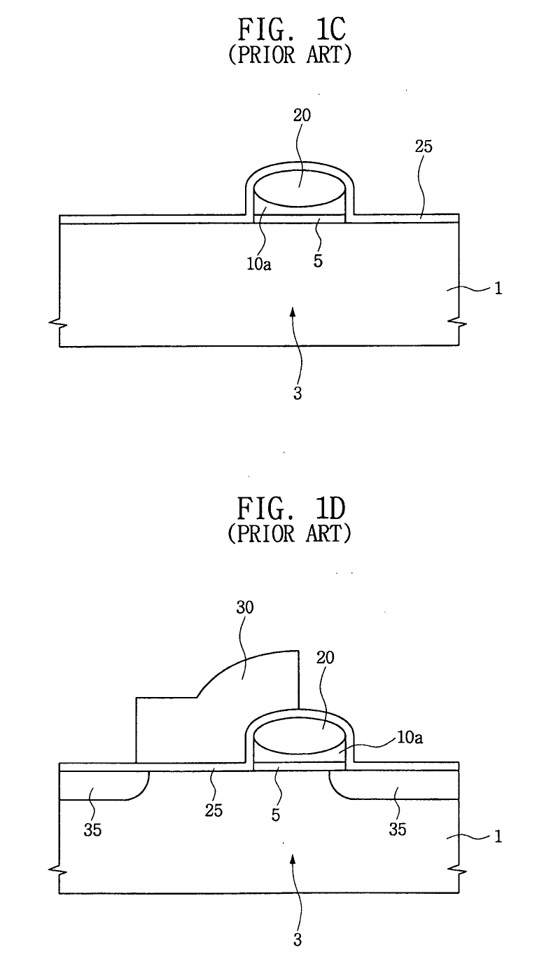

### DETAILED DESCRIPTION OF EXEMPLARY EMBODIMENTS

Exemplary embodiments of the present invention will now be described more fully hereinafter with reference to the accompanying drawings. This invention can, however, be embodied in different forms and should not be construed as limited to the embodiments set forth herein. In the drawings, the thickness of layers and regions are exaggerated for clarity. In addition, when a layer is described to be formed on other layer or on a substrate, which means that the layer can be formed on the other layer or on the substrate, or a third layer can be interposed between the layer and the other layer or the substrate. Other words used to describe the relationship between elements should be interpreted in a like fashion (e.g., “between” versus “directly between,” “adjacent” versus “directly adjacent,” etc.). Like numbers refer to like elements throughout the specification.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

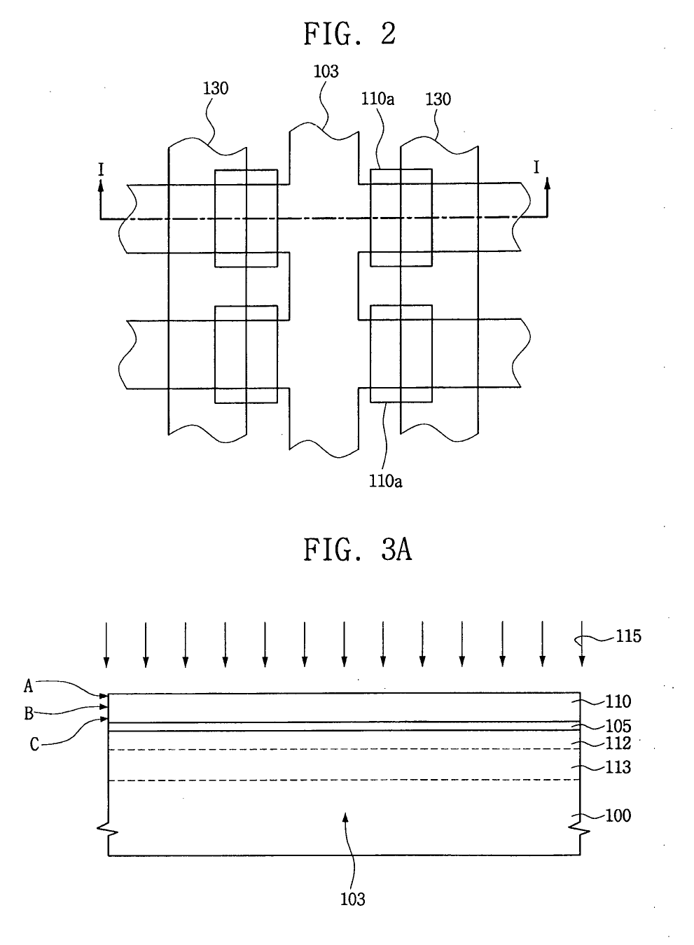

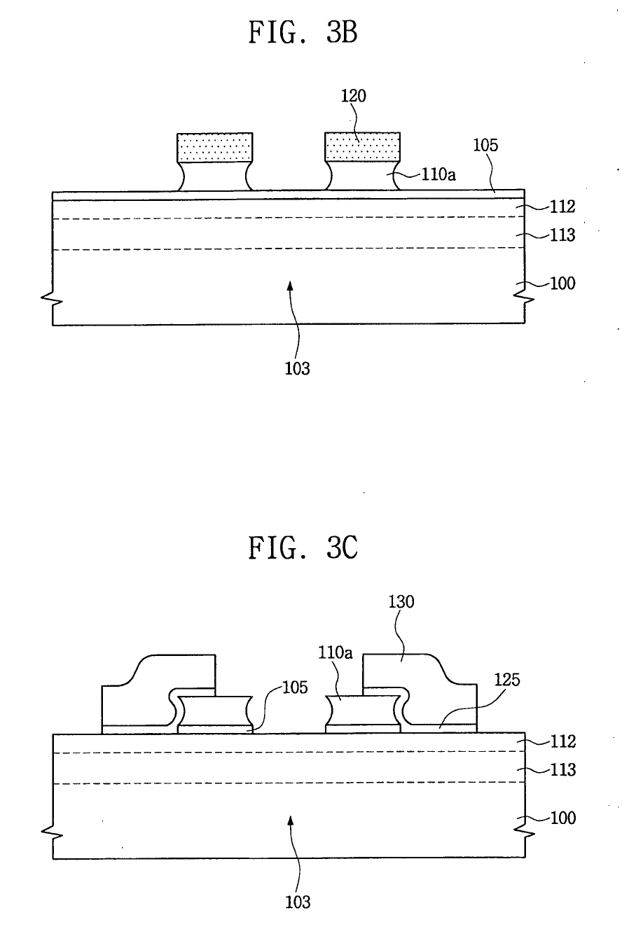

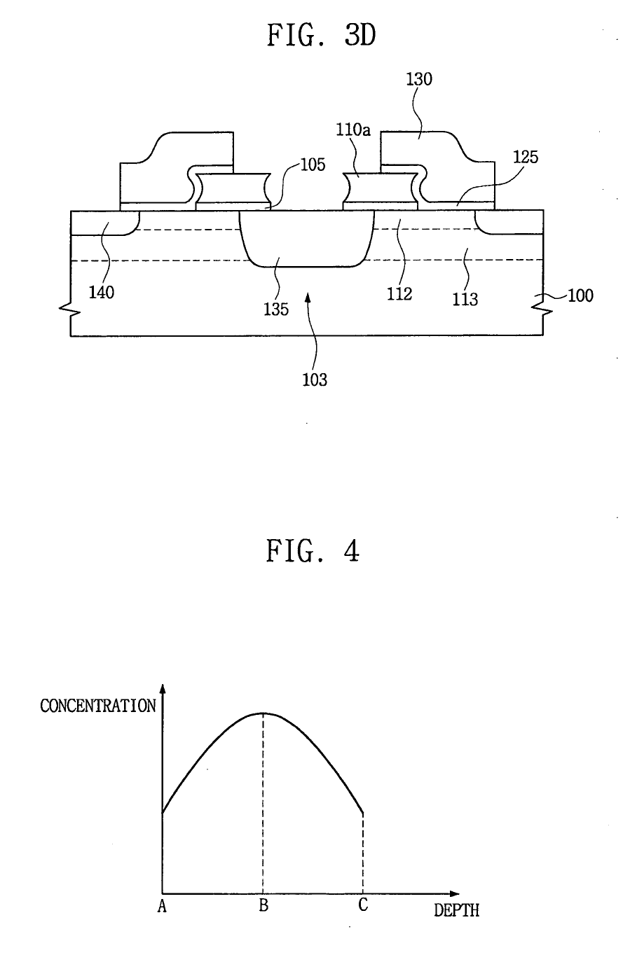

FIG. 2 is a plan view of an exemplary embodiment of a flash memory device according to an aspect of the present invention. FIGS. 3A to 3D are cross-sectional views of the device of FIG. 2 taken along line I-I′ to illustrate an exemplary embodiment of a method of fabricating a flash memory device. FIG. 4 is a graph schematically showing impurity concentrations depending on the depth of a conductive layer shown in FIG. 3A.

First, a method of fabricating an exemplary embodiment of a flash memory is device according to an aspect of the present invention will be described with reference to FIG. 2, FIGS. 3A to 3D, and FIG. 4.

Referring to FIGS. 2, 3A and 4, an isolation region (not shown in the drawings) can be formed on a semiconductor substrate 100 to define an active region 103. The semiconductor substrate 100 can be a silicon substrate. The isolation region can be formed using a trench isolation technique. A first dielectric layer 105 can be formed on the semiconductor substrate 100 having the active region 103. The first dielectric layer 105 can be a thermal oxide layer.

A first conductive layer 110 is formed on the semiconductor substrate 100 having the first dielectric layer 105. The first conductive layer 100 can contain implanted atoms. In the first conductive layer 110, the concentration of the implanted atoms can increase from an upper surface A to a middle portion B. In addition, in the first conductive layer 110, the concentration of the implanted atoms can decrease from the middle portion B to a bottom C. Therefore, in the first conductive layer 110, the concentration of the implanted atoms can be the highest at the middle portion B, as illustrated in FIG. 4.

Forming the first conductive layer 110 can include forming an undoped silicon layer on the semiconductor substrate 100 having the first dielectric layer 105, and implanting first impurity ions 115 into the undoped silicon layer using an ion implantation technique to form a silicon layer containing the implanted atoms. The undoped silicon layer can be an undoped polysilicon layer.

Meanwhile, a first channel impurity region 112 and a second channel impurity region 113 can be formed in the active region 103. The first and second channel impurity regions 112 and 113 can have the same conductivity type as the active region 103. The first channel impurity region 112 can be formed to be disposed at the upper surface portion of the active region 103 and have a higher impurity concentration than the active region 103. The second channel impurity region 113 can be formed at a lower level than the first channel impurity region 112 in the active region 103. The second channel impurity region 113 can be formed to have a higher impurity concentration than the first channel impurity region 112.

Before forming the first dielectric layer 105, the second channel impurity region 113 and the first channel impurity region 112 can be formed in sequence using the ion implantation technique. Alternatively, after forming the undoped silicon layer to form the first conductive layer 110, the second channel impurity region 113 and the first channel impurity region 112 can be formed in sequence using the ion implantation technique.

Meanwhile, although not shown in the drawings, during the ion implantation process of forming the first and second channel impurity regions 112 and 113, channel impurity ions can be implanted into a low-power transistor region. The ion implantation process of implanting channel impurity ions into the lower-power transistor region can be performed before or after forming the first and second channel impurity regions 112 and 113.

Referring to FIGS. 2 and 3B, a mask pattern 120 can be formed on the first conductive layer (110 of FIG. 3A). The mask pattern 120 can be formed of a photoresist pattern. Alternatively, the mask pattern 120 can be formed to include a silicon nitride layer. Subsequently, using the mask pattern 120 as an etch mask, the first conductive layer 110 can be etched to form first conductive patterns 110a. The first conductive patterns 110a can be narrowed from their upper surfaces (A of FIG. 3A) toward their middle portions (B of FIG. 3A). In other words, the first conductive patterns 110a can have negatively sloped sidewalls from the upper surfaces to the middle portions. In addition, the first conductive patterns 110a can widen from their middle portions toward their bottoms. In other words, the first conductive patterns 110a can have positively sloped sidewalls from their middle portions to their bottoms. Consequently, the first conductive patterns 110a can be formed to have concave sidewalls.

Etching the first conductive layer 110 can be performed using a dry etch process. More specifically, the first conductive layer 110 can be etched using a dry etch process in a process atmosphere including HBr gas, Cl₂ gas and HeO₂ gas. Since the etch rate of the middle portion of the first conductive layer 110 is higher than that of the upper surface or bottom of the first conductive layer, the first conductive patterns 110a can be formed to have the concave sidewalls. This is because the impurity concentration is highest at the middle portion B of the first conductive layer. In other words, since the concentration of the implanted atoms is highest at the middle portion B of the first conductive layer 110, the middle portion B of the first conductive layer 110 can be etched faster than the upper surface A and the bottom (C of FIG. 3A) of the first conductive layer 110.

The dry etch process can include a main etch process and an over etch process. During the over etch process, the middle portions of the sidewalls of the first conductive patterns 110a can be further concave.

Referring to FIGS. 2 and 3C, the mask pattern (120 of FIG. 3B) can be removed. And, the first dielectric layer 105 of both sides of the first conductive pattern 110a can be etched.

Meanwhile, the implanted atoms can be diffused and uniformly distributed into the first conductive patterns 110a by performing a thermal process. The thermal process can be replaced by an annealing process for a first impurity region to be mentioned below.

Subsequently, second dielectric layers 125 can be formed on the semiconductor substrate having the first conductive patterns 110a. The second dielectric layers 125 can be formed of a thermal oxide layer and/or a chemical vapor deposition (CVD) oxide layer. For example, forming the second dielectric layers 125 can include forming a thermal oxide layer on the semiconductor substrate having the first conductive patterns 110a and forming a CVD oxide layer on the thermal oxide layer.

Meanwhile, although not shown in the drawings, the second dielectric layers 125 formed in the low-power transistor region can be selectively removed, and a gate dielectric layer thinner than the second dielectric layers 125 can be formed in the low-power transistor region.

A second conductive layer can be formed on the semiconductor substrate having the second dielectric layers 125. By patterning the second conductive layer, second conductive patterns 130 crossing the active region 103 and overlapping the first conductive patterns 110a can be formed. The second conductive patterns 130 can be formed to cross the active region 103 adjacent to the first conductive patterns 110a and partially cover the first conductive patterns 110a. Here, the second conductive patterns 130 can be formed to cover sidewalls of the first conductive patterns 110a and partially overlap the upper surfaces of the first conductive patterns 110a. The second conductive patterns 130 can be formed of a doped polysilicon layer containing impurities or a polycide layer. Here, the polycide layer can include a doped polysilicon layer and a metal silicide layer stacked in sequence.

The second conductive patterns 130 and the first conductive patterns 110a can be spaced apart from each other by the thickness of the second dielectric layers 125. In other words, the second conductive patterns 130 can cover sidewalls and the upper surfaces of the first conductive patterns 110a at a uniform distance from the first conductive patterns 110a.

Each of the second dielectric layers 125 can have a gentle curve at a portion where it is adjacent to the second conductive pattern 130, the first conductive pattern 110a and the active region 103 together. Thus, it is possible to prevent an electric field from concentrating on the portion where each of the second dielectric layers 125 is adjacent to the second conductive pattern 130, the first conductive pattern 110a and the active region 103 together. Consequently, the reliability of the second dielectric layers 125 can be improved.

Meanwhile, while patterning the second conductive layer, the second conductive layer is patterned to leave a part of the second conductive layer on the low-power transistor region, so that a gate electrode of a low-power transistor can be formed.

Referring to FIG. 3D, a first impurity region 135 can be formed by implanting impurity ions having a different conductivity type from the active region 103 into the active region 103 adjacent to the first conductive patterns 110a. The first impurity region 135 can contain implanted phosphorus (Ph) atoms. In other words, the first impurity region 135 can be formed in the active region 103 opposite to the second conductive patterns 130 from the viewpoint of the first conductive patterns 110a.

Subsequently, by performing an annealing process, the impurity atoms implanted into the first impurity region 135 can be diffused and electrically activated.

Meanwhile, during the annealing process, the atoms implanted into the first conductive patterns 110a can be diffused and electrically activated. As a result, the atoms implanted into the first conductive patterns 110a can be uniformly distributed into the first conductive patterns 110a.

In addition, during the annealing process, the impurity atoms in the second conductive patterns 130 can be electrically activated.

By implanting impurity ions having a different conductivity type from the active region 103 into the active region 103 adjacent to the second conductive patterns 130, second impurity regions 140 can be formed. The second impurity regions 140 can include implanted arsenic (As) atoms. Subsequently, by performing an annealing process, the impurity atoms implanted into the second impurity regions 140 can be diffused and electrically activated. Here, the second impurity regions 140 can be formed to be shallower junctions than the first impurity region 135.

In this exemplary embodiment, the first conductive patterns 110a can be defined as floating gates, and the second conductive patterns 130 can be defined as control gates. In addition, the first impurity region 135 can be defined as a source region, and the second impurity regions 140 can be defined as drain regions. Consequently, it is possible to provide a flash memory device having a split-gate structure.

As described above, a high-temperature process is not performed to form the first conductive patterns 110a, i.e., floating gates. Therefore, during the process of forming the floating gates 110a, it is possible to prevent heat damage from occurring in a channel region of the low-power transistor. As a result, the flash memory device employing the floating gates according to this exemplary embodiment can be easily combined with a logic device including a low-power transistor.

In addition, in comparison with a process of forming a floating gate by a conventional local oxidation of silicon (LOCOS) process, the process time can be reduced, and thus productivity can be improved.

The structure of the flash memory device according to an exemplary embodiment of the present invention will be described below with reference to FIGS. 2 and 3D.

Referring to FIGS. 2 and 3D, an isolation region (not shown in the drawings) can be disposed on a semiconductor substrate 100 to define an active region 103. The semiconductor substrate 100 can be a silicon substrate. First conductive patterns 110a are disposed on the semiconductor substrate 100 having the active region 103. The first conductive patterns 110a can be disposed on the active region 103. The first conductive patterns 110a on the active region 103 can have flat upper surfaces and can narrow from the upper surfaces to their middle portions. In addition, the first conductive patterns 110a can widen from their middle portions to their bottoms. The first conductive patterns 110a can have concave sidewalls. First dielectric layers 105 can be disposed between the active region 103 and the first conductive patterns 110a. The first dielectric layers 105 can include a thermal oxide layer.

Second conductive patterns 130 can be disposed to cross the active region 103 adjacent to the first conductive patterns 110a and partially cover the first conductive patterns 110a. The second conductive patterns 130 can cover sidewalls of the first conductive patterns 110a and partially overlap the upper surfaces of the first conductive patterns 110a. The second conductive patterns 130 can be formed of a doped polysilicon layer or a polycide layer. Here, the polycide layer can include a doped polysilicon layer and a metal silicide layer stacked in sequence.

Second dielectric layers 125 can be disposed between the second conductive patterns 130 and the first conductive patterns 110a and between the second conductive patterns 130 and the active region 103. The second dielectric layers 125 can be formed of a thermal oxide layer and/or a CVD oxide layer. The second conductive patterns 130 and the first conductive patterns 110a can be spaced apart by the thickness of the second dielectric layers 125. In other words, the second conductive patterns 130 can cover sidewalls and the upper surfaces of the first conductive patterns 110a at a uniform distance from the first conductive patterns 110a.

Each of the second dielectric layers 125 can have a gentle curve at a portion where it is adjacent to the second conductive pattern 130, the first conductive pattern 110a and the active region 103 together. Thus, it is possible to prevent an electric field from concentrating on the portion where each of the second dielectric layers 125 is adjacent to the second conductive pattern 130, the first conductive pattern 110a and the active region 103 together. Consequently, the reliability of the second dielectric layers 125 can be improved.

In the active region 103 adjacent to the first conductive patterns 110a, a first impurity region 135 having a different conductivity type from the active region 103 can be disposed. The first impurity region 135 can contain Ph atoms.

In the active region 103 adjacent to the second conductive patterns 130, second impurity regions 140 having a different conductivity type from the active region 103 can be disposed. The second impurity regions 140 can contain As atoms. Here, the second impurity regions 140 can be shallower junctions than the first impurity region 135.

In the active region 103, a first channel impurity region 112 and a second channel impurity region 113 can be disposed. The first and second channel impurity regions 112 and 113 can have the same conductivity type as the active region 103. The first channel impurity region 112 can be disposed at the upper surface portion of the active region 103 between the first impurity region 135 and the second impurity regions 140. And, the first channel impurity region 112 can be formed to have a higher impurity concentration than the active region 103. The second channel impurity region 113 can be disposed at a lower level than the first channel impurity region 112 in the active region 103. And, the second channel impurity region 113 can have a higher impurity concentration than the first channel impurity region 112.

In this exemplary embodiment, the first conductive patterns 110a can be defined as floating gates, and the second conductive patterns 130 can be defined as control gates. In addition, the first impurity region 135 can be defined as a source region, and the second impurity regions 140 can be defined as drain regions. Consequently, it is possible to provide a flash memory device having a split-gate structure.

According to the above described embodiments and aspects of the present invention, upper edges of floating gates can be sharply formed without a high-temperature process. More specifically, a silicon layer in which the concentration of implanted atoms increases from the upper surface toward the middle portion is formed and etched, and thus it is possible to form floating gates narrowing from their upper surfaces toward their middle portions. In addition, since a high-temperature process is not performed in a process of forming the floating gates, it is possible to prevent heat damage from occurring in a channel region of a low-power transistor. Consequently, the flash memory device in accordance with the present invention having a split-gate structure can be easily combined with a logic device having a low-power transistor.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details can be made without departing from the spirit and scope of the present invention as set forth in the following claims.

What is claimed is:

1. A method of fabricating a flash memory device, comprising:
forming a first dielectric layer on an active region of a semiconductor substrate;
forming a first conductive layer on the first dielectric layer;
forming a mask pattern on the first conductive layer;
etching the first conductive layer using the mask pattern as an etch mask to form a first conductive pattern narrowing from its upper surface toward its middle portion;
forming a second dielectric layer on the semiconductor substrate having the first conductive pattern; and
on the semiconductor substrate having the second conductive layer, forming a second conductive pattern crossing the active region adjacent to the first conductive pattern and partially covering the first conductive pattern.

2. The method according to claim 1, wherein the first conductive layer contains implanted atoms.

3. The method according to claim 2, wherein the concentration of the implanted atoms in the first conductive layer increases from an upper surface of the first conductive layer toward a middle portion of the first conductive layer.

4. The method according to claim 3, wherein the concentration of the implanted atoms in the first conductive layer decreases from the middle portion of the first conductive layer toward a bottom of the first conductive layer.

5. The method according to claim 2, wherein forming the first conductive layer comprises:
forming an undoped silicon layer on the semiconductor substrate having the first dielectric layer; and
implanting first impurity ions into the undoped silicon layer to form a silicon layer containing the implanted atoms.

6. The method according to claim 2, further comprising:
after forming the second conductive pattern, performing a thermal process so that the implanted atoms are diffused and uniformly distributed into the first conductive pattern.

7. The method according to claim 2, wherein the implanted atoms comprise at least one of phosphorus (Ph) and arsenic (As).

8. The method according to claim 1, wherein the first conductive pattern is widened from its middle portion to its bottom.

9. The method according to claim 1, wherein the first conductive pattern is formed to have concave sidewalls.

10. The method according to claim 1, wherein the first conductive layer is etched using a dry etch process.

11. The method according to claim 1, further comprising:
forming a first photoresist pattern having a first opening exposing a portion of the active region adjacent to the first conductive pattern on the semiconductor substrate having the second conductive pattern;
implanting impurity ions into the active region exposed through the first opening using the first photoresist pattern as an ion implantation mask to form a first impurity region;
removing the first photoresist pattern; and
performing a first annealing process for activating the impurity ions implanted into the first impurity region.

12. The method according to claim 11, further comprising:
forming a second photoresist pattern having a second opening exposing the active region adjacent to the second conductive pattern on the semiconductor substrate having the second conductive pattern;
implanting impurity ions into the active region exposed through the second opening using the second photoresist pattern as an ion implantation mask to form a second impurity region;
removing the second photoresist pattern; and
performing a second annealing process for activating the impurity ions implanted into the second impurity region.

13. The method according to claim 12, wherein the second annealing process is performed at a lower temperature than the first annealing process.

14. A flash memory device, comprising:
a first conductive pattern disposed on an active region of a semiconductor substrate, the first conductive pattern having a flat upper surface and narrowing from its upper surface toward its middle portion;
a first dielectric layer interposed between the first conductive pattern and the active region;
a second conductive pattern crossing the active region adjacent to the first conductive pattern and overlapping the first conductive pattern; and
a second dielectric layer having a portion interposed between the second conductive pattern and the first conductive pattern and another portion interposed between the second conductive pattern and the active region.

15. The flash memory device according to claim 14, wherein the first conductive pattern is formed of a doped silicon layer.

16. The flash memory device according to claim 14, wherein the second conductive pattern covers sidewalls of the first conductive pattern while partially overlapping the upper surface of the first conductive pattern.

17. The flash memory device according to claim 14, wherein the first conductive pattern is spaced apart from the second conductive pattern by the thickness of the second dielectric layer.

18. The flash memory device according to claim 14, wherein the first conductive pattern is widened from its middle portion to its bottom.

19. The flash memory device according to claim 14, wherein the first conductive pattern has concave sidewalls.

20. The flash memory device according to claim 14, further comprising:
a first impurity region disposed in the active region adjacent to the first conductive pattern; and
a second impurity region disposed in the active region adjacent to the second conductive pattern,
wherein the second impurity region is a shallower junction than the first impurity region.
